(19) United States
(12) Patent Application Publication
(10) Pub. No.: US 2019/0115704 A1
(43) Pub. Date: Apr. 18, 2019

(54) CONDUCTIVE TERMINALS, BUSBARS, AND METHODS OF PREPARING THE SAME, AND METHODS OF ASSEMBLING RELATED POWER

(71) Applicant: Kulicke and Soffa Indsutries,Inc., Fort Washington, PA (US)

(72) Inventors: Theodore J. Copperthite, Laguna Hills, CA (US); Omid Niayesh, Irvine, CA (US)

(21) Appl. No.: 16/158,401

(22) Filed: Oct. 12, 2018

Related U.S. Application Data
(60) Provisional application No. 62/572,055, filed on Oct. 13, 2017.

(51) Int. Cl. H01R 25/16; H01R 43/02; H01R 43/16; H01R 4/02; H05K 3/32; H05K 1/18; B23K 20/10

(52) U.S. Cl. CPC H01R 25/162; H01R 43/0207; H01R 43/16; H01R 4/029; B23K 2101/36; H05K 1/18; B23K 20/10; H05K 2201/10272; H05K 3/328

(57) ABSTRACT

A terminal configured to be ultrasonically welded to a substrate is provided. The terminal includes a conductive body portion including a contact portion configured to be ultrasonically welded to a substrate. The contact portion has a non-planar bonding surface.

### CROSS-REFERENCE TO RELATED APPLICATION

This application claims the benefit of U.S. Provisional Application 62/572,055, filed Oct. 13, 2017, the contents of which are incorporated herein by reference.

### FIELD

This invention relates to terminals and busbars, and more specifically, to terminals and busbars configured for bonding to a substrate.

### BACKGROUND

In various applications, it is desirable to electrically connect conductive terminals (e.g., thick copper terminals) to substrates (e.g., copper substrates). Exemplary applications include high electrical power applications, high electrical current applications (e.g., power converters, batteries, etc.), among others. Exemplary power converters and other power modules may be used in high power applications such as locomotives, EVs (electric vehicles), wind turbines, etc.

Exemplary conductive terminals may be extensions from copper busbars that transfer power from multiple locations/components inside a package to connections on the outside of a package; however, sometimes copper terminals form single leads extending only to the outside of a package. Copper busbars may also be completely inside an electronic package, and only transfer electrical power from one location within the package to another location within the package.

Exemplary substrates include: (i) a DBC (Direct Bonded Copper) assembly that forms a well-controlled surfaced for other components; and (ii) copper plates or other copper strips that properly route electrical power.

A goal is to make a strong physical connection between the terminal and the substrate, to provide a robust interconnect for real-world application. A typical measure of the strength of such a connection is the maximum pull force (e.g., a pull force normal to the substrate) that can be applied to the terminal before it fails or separates. A higher pull force generally indicates a better connection between the terminal and the substrate.

There are various methods which may be used to form an electrical interconnect between the terminal and the substrate. Ultrasonic welding may be considered a particularly attractive option because it is a relatively fast, low cost process that is robust and well controlled. Further, ultrasonic welding is a relatively environmentally clean process that typically does not involve the use of damaging solvents.

Thus, it would be desirable to provide improved systems and processes for ultrasonic welding between a terminal (e.g., a copper terminal) and a substrate (e.g., a copper substrate).

### SUMMARY

According to an exemplary embodiment of the invention, a terminal configured to be ultrasonically welded to a substrate is provided. The terminal includes a conductive body portion having a contact portion configured to be ultrasonically welded to a substrate. The contact portion has a non-planar bonding surface.

According to another exemplary embodiment of the invention, a busbar for providing electrical interconnection in a power module is provided. The busbar includes a conductive distribution body portion, and a plurality of conductive terminals extending from the conductive distribution body portion. Each of the plurality of conductive terminals includes a conductive body portion having a contact portion configured to be ultrasonically welded to a substrate. The contact portion has a non-planar bonding surface.

According to yet another exemplary embodiment of the invention, a method of preparing a terminal configured to be ultrasonically welded to a substrate is provided. The method includes the steps of: (a) providing a terminal including a conductive body portion, the conductive body portion including a contact portion; and (b) varying a profile of the contact portion such that the contact portion has a non-planar bonding surface, the contact portion being configured to be ultrasonically welded to a substrate.

According to yet another exemplary embodiment of the invention, a method of preparing a busbar configured to be ultrasonically welded to a substrate is provided. The method includes the steps of: (a) providing a busbar for providing electrical interconnection in a power module, the busbar including a conductive distribution body portion and a plurality of conductive terminals extending from the conductive distribution body portion, each of the plurality of conductive terminals including a conductive body portion having a contact portion configured to be ultrasonically welded to a substrate; and (b) varying a profile of the contact portion such that the contact portion has a non-planar bonding surface, the contact portion being configured to be ultrasonically welded to the substrate.

According to yet another exemplary embodiment of the invention, a method of assembling a power module is provided. The method includes: (a) providing a substrate for inclusion in a power module; (b) aligning a busbar in connection with the substrate, the busbar for providing electrical interconnection in the power module, the busbar including a conductive distribution body portion and a plurality of conductive terminals extending from the conductive distribution body portion, each of the plurality of conductive terminals including a conductive body portion having a contact portion configured to be ultrasonically welded to the substrate, the contact portion having a non-planar bonding surface; and (c) ultrasonically welding the contact portion of each of the plurality of conductive terminals to a corresponding portion of the substrate.

According to yet another exemplary embodiment of the invention, another method of assembling a power module is provided. The method includes: (a) aligning a conductive terminal with a bonding location of the power module, the conductive terminal for providing electrical interconnection in the power module, the conductive terminal including a conductive body portion having a contact portion configured to be ultrasonically welded to the bonding location, the contact portion having a non-planar bonding surface; and (b) ultrasonically welding the contact portion of the conductive terminal to the bonding location.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1A is a perspective view of a busbar in accordance with an exemplary embodiment of the invention;

FIG. 1B is a detailed view of a portion of a terminal of the busbar of FIG. 1A;

FIG. 2A is a perspective view of a busbar in accordance with another exemplary embodiment of the invention;

FIG. 2B is a detailed view of a portion of a terminal of the busbar of FIG. 2A;

FIGS. 3A-3H are detailed views of portions of terminals in accordance with various exemplary embodiments of the invention;

FIGS. 4A-4C are block diagrams illustrating a method of preparing a terminal in accordance with an exemplary embodiment of the invention;

FIG. 5 is a block diagram illustrating elements of a system for preparing a terminal in accordance with an exemplary embodiment of the invention;

FIGS. 6A-6C are block diagrams illustrating another method of preparing a terminal in accordance with an exemplary embodiment of the invention;

FIG. 7 is a block diagram illustrating elements of another system for preparing a terminal in accordance with an exemplary embodiment of the invention

FIGS. 8A-8B are block diagrams illustrating yet another method of preparing a terminal in accordance with an exemplary embodiment of the invention;

FIGS. 9A-9B are block diagrams illustrating yet another method of preparing a terminal in accordance with an exemplary embodiment of the invention;

FIGS. 10A-10D are block diagrams illustrating a method of assembling a power module in accordance with an exemplary embodiment of the invention;

FIGS. 11A-11E are block diagrams illustrating another method of assembling a power module in accordance with another exemplary embodiment of the invention;

FIG. 12 is a flow diagram illustrating a method of preparing a terminal configured to be ultrasonically welded to a substrate in accordance with an exemplary embodiment of the invention;

FIG. 13 is a flow diagram illustrating a method of preparing a busbar configured to be ultrasonically welded to a substrate in accordance with an exemplary embodiment of the invention;

FIG. 14 is a flow diagram illustrating a method of assembling a power module in accordance with an exemplary embodiment of the invention; and

FIG. 15 is a flow diagram illustrating another method of assembling a power module in accordance with an exemplary embodiment of the invention.

### DETAILED DESCRIPTION

Certain exemplary embodiments of the invention relate to high power ultrasonic welding systems, and methods of using the same, for example, in connection with power modules. Such ultrasonic welding systems maybe used for welding copper terminals (or other conductive terminals) to a copper substrate or some other conductive region (e.g., a conductive region in a power module).

Ultrasonic welding systems typically include an ultrasonic welding transducer. Such transducers may be designed to operate, for example, in a linear mode/motion, or in a torsional mode/motion. For example, a linear ultrasonic transducer carries a sonotrode, and during operation the foot portion of the sonotrode will vibrate ultrasonically in a substantially linear motion. In contrast, a torsional ultrasonic transducer carries a sonotrode, and during operation the foot portion of the sonotrode will vibrate ultrasonically in a substantially rotational motion.

In accordance with the invention, it is desirable that conductive terminals and substrates are properly cleaned to remove contaminants including both organic such as oils or other processing films, and non-organic such as oxidation, particulates, etc.

Conventional substrates (the welded side) are almost universally substantially flat, or planar, surfaces, with varying degrees of surface roughness. Conventional terminals typically have an underside (the welded side) that has a substantially flat profile.

According to aspects of the invention, non-planar bonding surface is provided on a contact portion of a terminal. The contact portion, and the non-planar bonding surface, may be considered to have a non-planar profile. Examples of non-planar profiles including a sloped profile, an angled profile, a curved profile, among others described herein and/or within the scope of the invention. Thus, the non-planar bonding surface of the contact portion (e.g., on the underside of a terminal, that is, the to be welded side) can substantially improve the strength of welded terminal connection (e.g., ultrasonically welded terminals). Exemplary test results have illustrated increased pull strength values at 2 or 3 times that of a conventional flat, or planar, terminal. For example, testing has shown that a substantially planar terminal exhibited the lowest pull strength (e.g., a pull strength of 348 N). Exemplary terminals including a non-planar bonding surface in accordance with the invention have exhibited improved pull strength values of 744 N, 882 N, 1050 N, 1119 N, and 1135 N. The tests described herein were run with consistent parameters for each condition. These tests are run with 5 mm wide copper terminals that are 1.5 mm thick. The welded area was approximately 4 mm×4 mm.

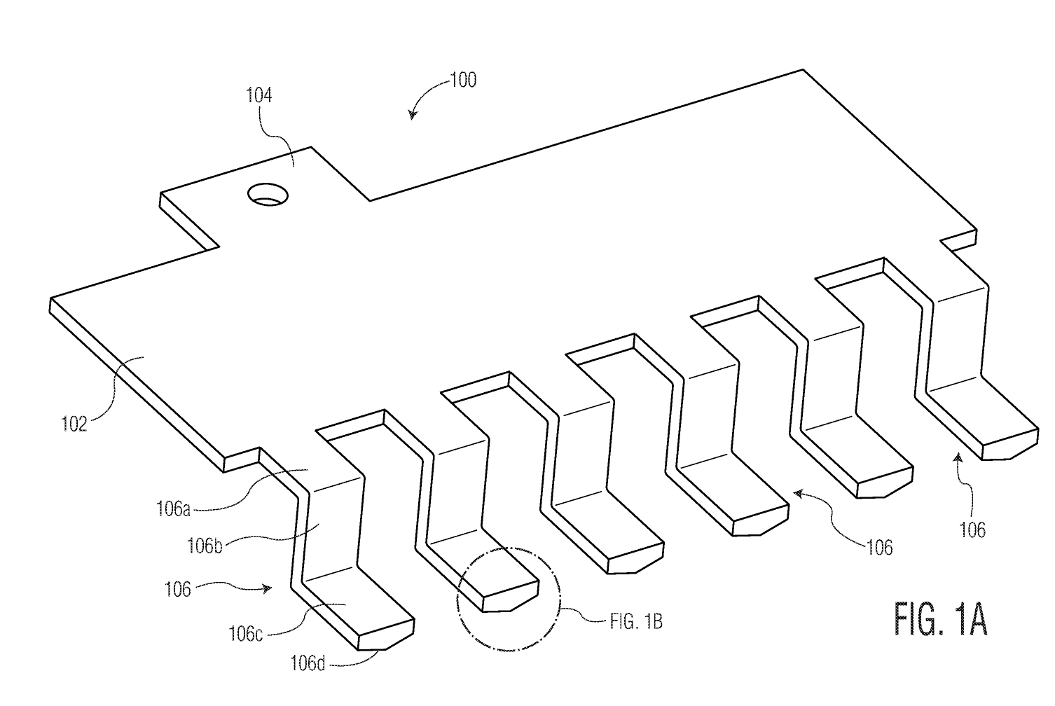

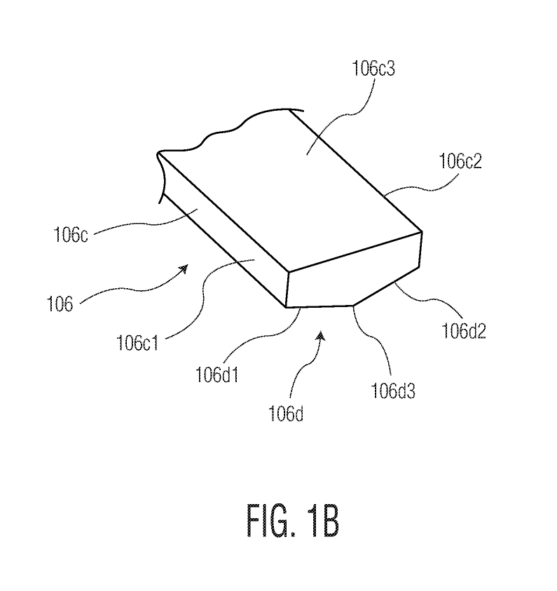

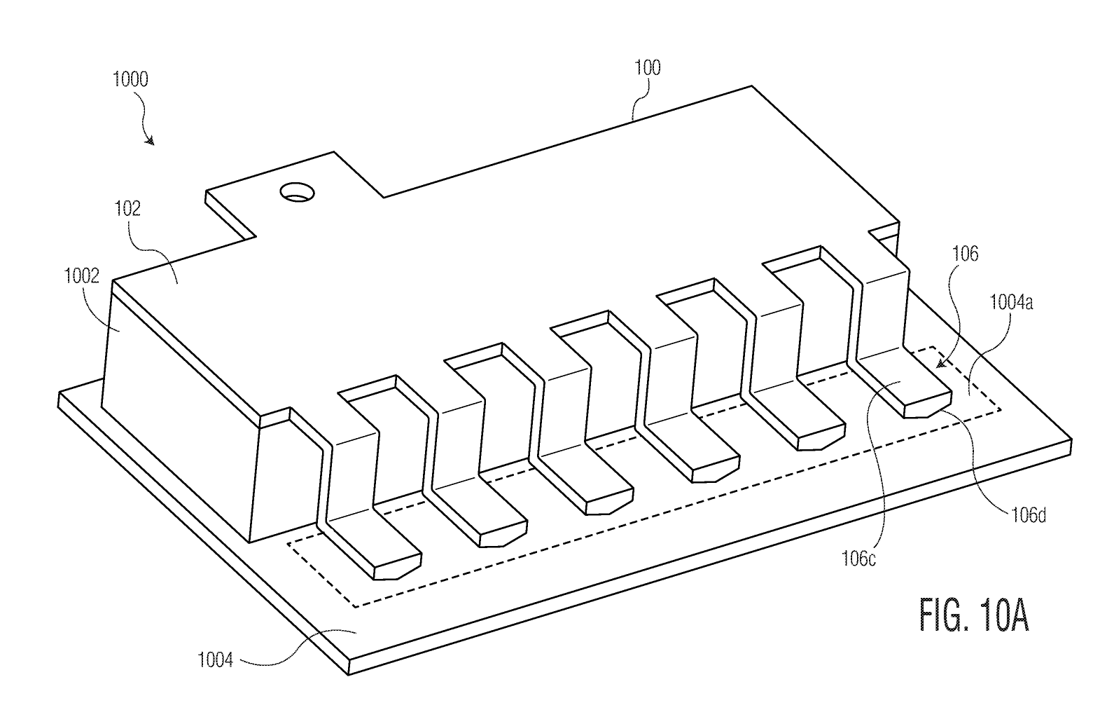

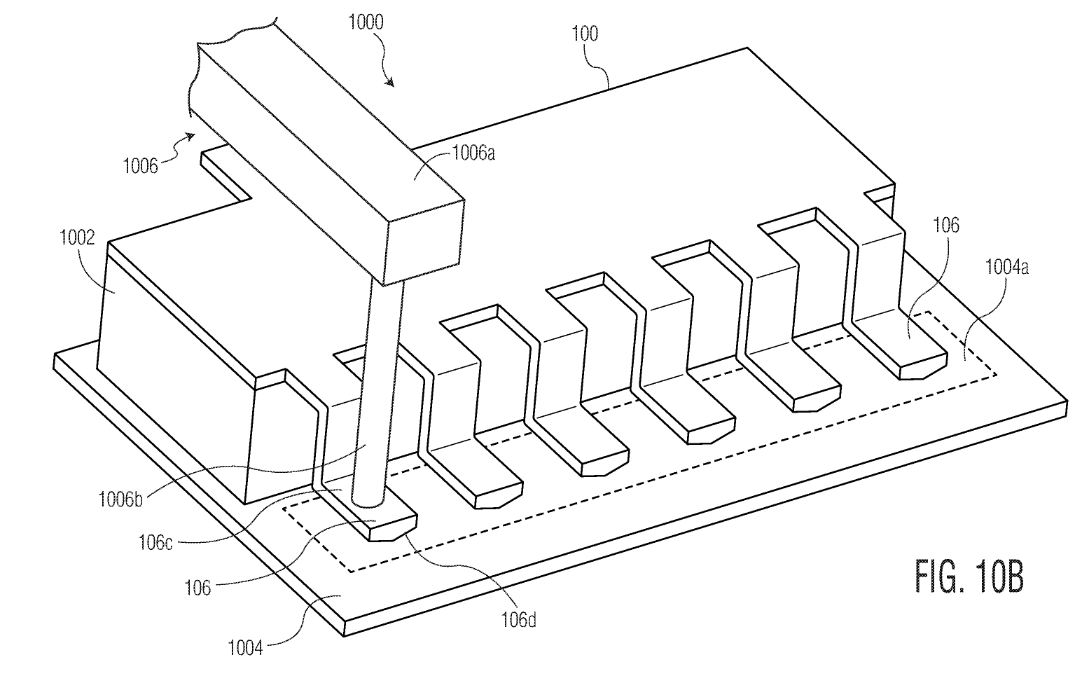

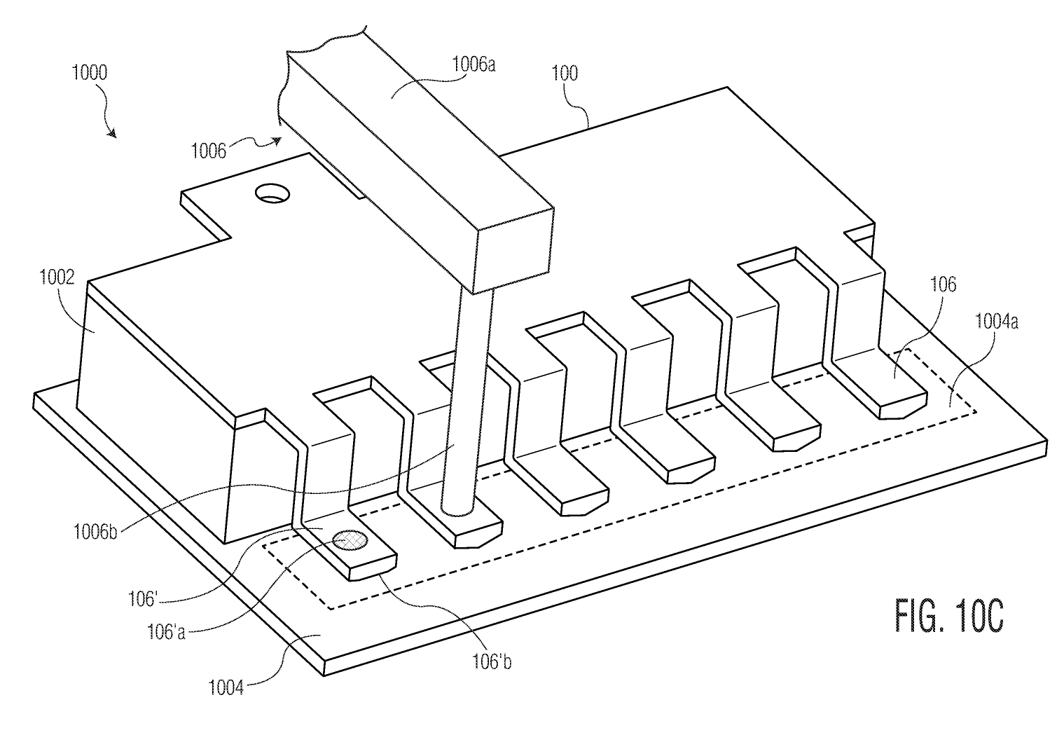

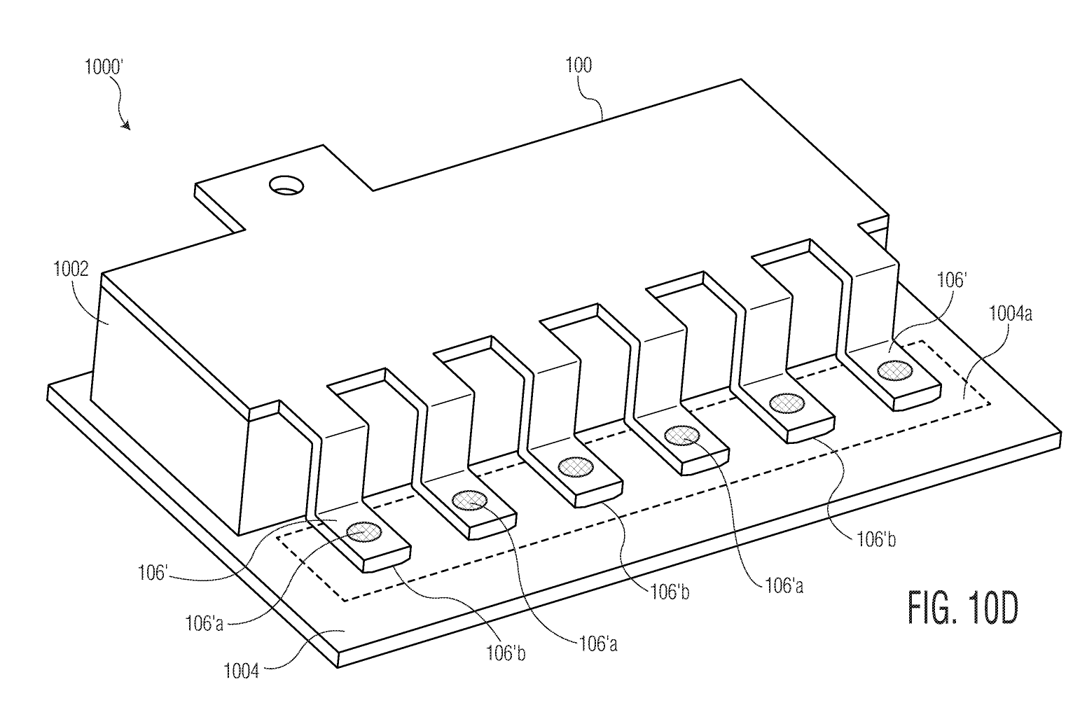

Referring now to the drawings, FIG. 1A illustrates a busbar 100 prepared in accordance with an exemplary embodiment of the invention. Busbar 100 includes conductive distribution body portion 102 (also referred to as “body portion 102”), tab 104 (e.g., for electrical interconnection with another structure, either inside or outside of the relevant power module), and plurality of terminals 106 extending from conductive distribution body portion 102. Terminals 106 are configured to be ultrasonically welded to a substrate (e.g., see FIGS. 10A-10D) and may be formed from a copper material. Body portion 102, and the plurality of conductive terminals 106, may be formed from a unitary piece of conductive material, for example, a copper material.

Terminals 106 each include a conductive body portion; in the example shown FIG. 1A the conductive body portion has a “step down” shape. The conductive body portion includes upper terminal portion 106a, downward terminal portion 106b, and contact portion 106c. Contact portion 106c is the portion of terminal 106 configured to be ultrasonically welded to another conductive location (e.g., to a conductive portion of a substrate). Contact portion 106c includes non-planar bonding surface 106d (i.e., on the underside of contact portion 106c illustrated in FIGS. 1A-1B). Because of non-planar bonding surface 106d, contact portion 106c of terminal 106 in FIGS. 1A-1B, has a “pointed” or “peaked” profile. FIG. 1B is a detailed view of a portion of terminal 106 of busbar 100 of FIG. 1A taken at circle “FIG. 1B”. More specifically, FIG. 1B illustrates contact portion 106c. Contact portion 106c includes opposing sidewalls 106c1, 106c2 and upper surface 106c3. Non-planar bonding surface 106d is defined by opposing downwardly sloped sides 106d1, 106d2, joining at “peak” 106d3 (peak 106d3 may also be considered an “apex”).

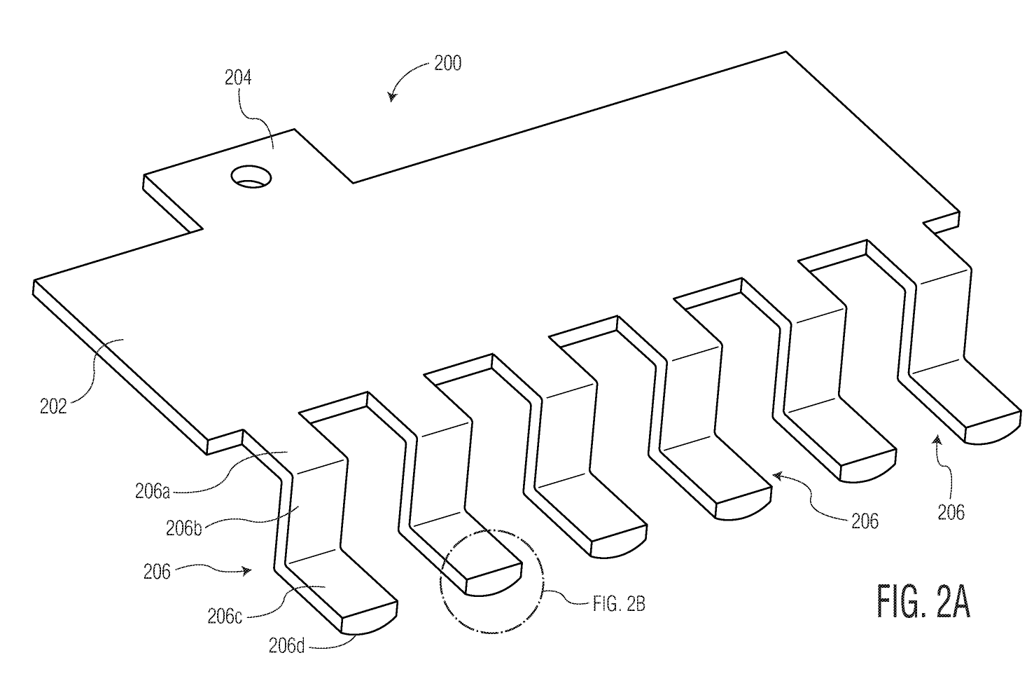

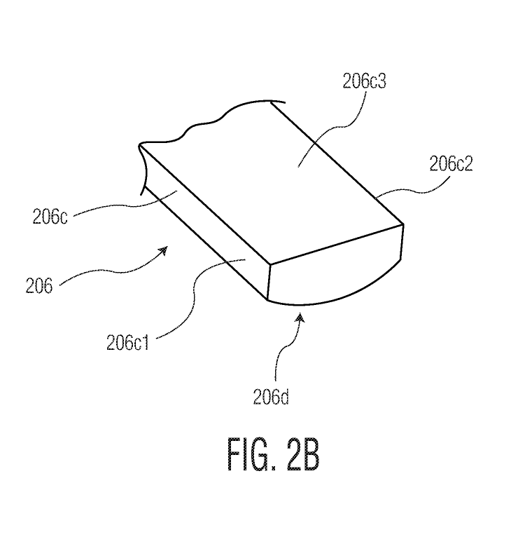

FIG. 2A illustrates another busbar 200 prepared in accordance with another exemplary embodiment of the invention. Busbar 200 includes conductive distribution body portion 202, tab 204, and plurality of terminals 206 extending from conductive distribution body portion 202. Terminals 206 are configured to be ultrasonically welded to a substrate (e.g., see FIGS. 10A-10D) and may be formed from a copper material. Conductive distribution body portion 202 and the plurality of conductive terminals 206 may be formed from a unitary piece of conductive material, for example, a copper material.

Terminals 206 each include a conductive body portion; in the example shown FIG. 2A the conductive body portion has a “step down” shape. The conductive body portion includes upper terminal portion 206a, downward terminal portion 206b, and contact portion 206c. Contact portion 206c is the portion of terminal 206 configured to be ultrasonically welded to another conductive location (e.g., to a conductive portion of a substrate). Contact portion 206c includes non-planar bonding surface 206d (i.e., on the underside of contact portion 206c illustrated in FIGS. 2A-2B). Non-planar bonding surface 206d of terminal 206 in FIGS. 2A-2B, has a “curved” or “arc-shaped” profile. FIG. 2B is a detailed view of a portion of terminal 206 of busbar 200 of FIG. 2A taken at circle “FIG. 2B”. More specifically, FIG. 2B illustrates contact portion 206c. Contact portion 206c includes opposing sidewalls 206c1, 206c2 and upper surface 206c3. Side walls 206c1, 206c2 are joined by the non-planar (curved) bonding surface 206d.

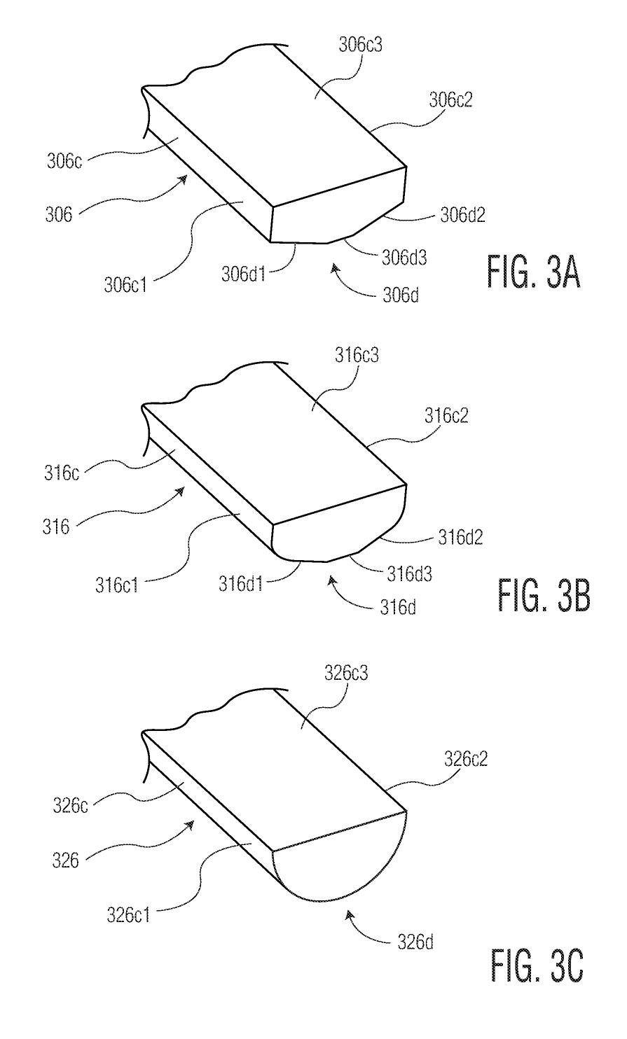

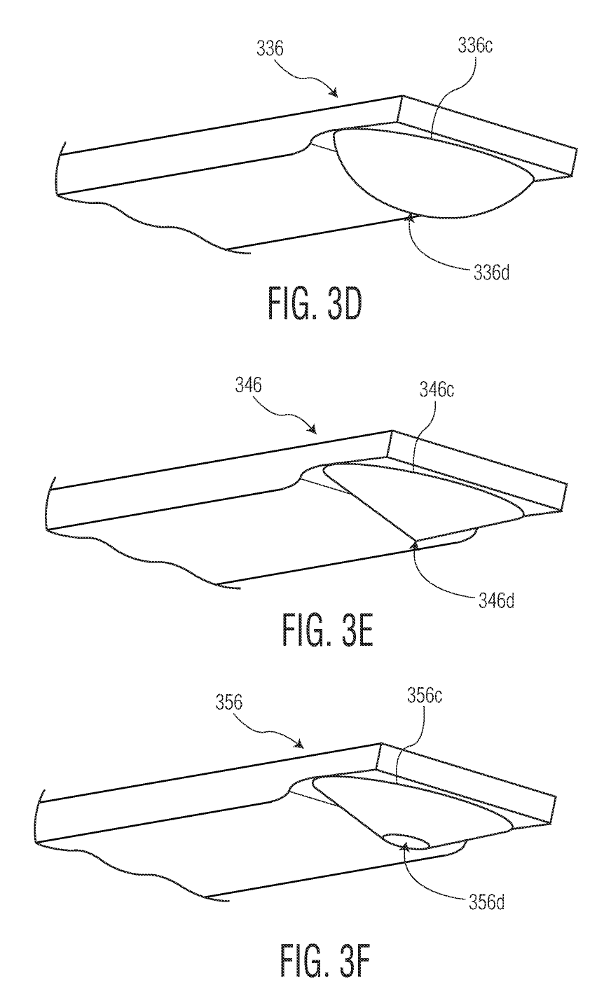

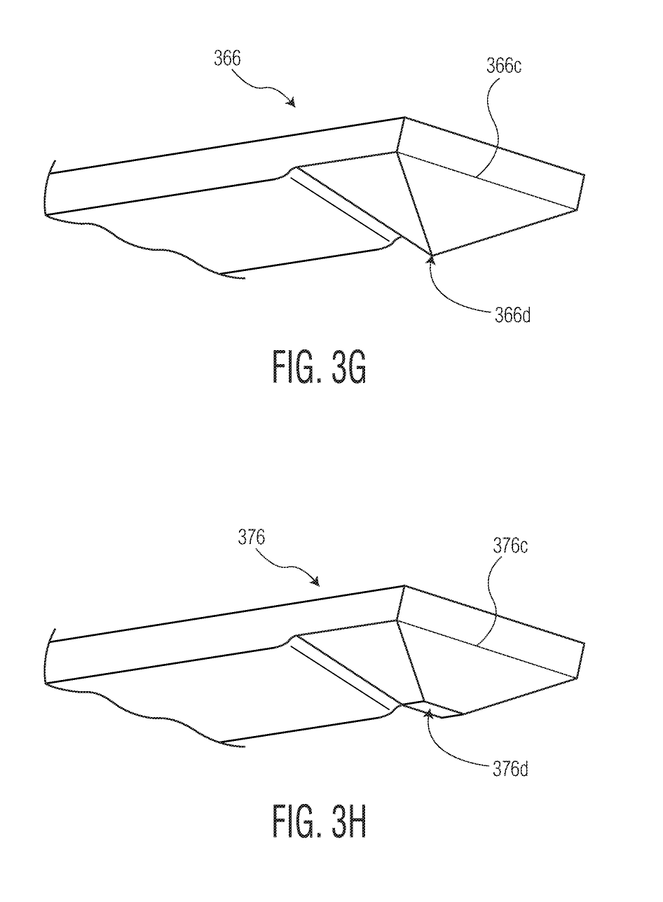

Thus, FIGS. 1A-1B and FIGS. 2A-2B are examples of busbars 100, 200 including two exemplary terminal configurations (e.g., terminals 106 having a peaked bonding surface 106d, and terminals 206 having a curved bonding surface 206d). It will be appreciated that, in accordance with the invention, many different non-planar bonding surfaces for terminals are contemplated. FIGS. 3A-3H are examples of such terminals 306, 316, 326, 336, 346, 356, 366, and 376. Such terminals (like terminals 106, 206) may be included as part of a busbar (similar to busbars 100, 200, or other busbars), as a terminal to be ultrasonically welded in a power module independent of a busbar, among other implementations.

FIG. 3A illustrates contact portion 306c of terminal 306. Contact portion 306c includes upper surface 306c3, opposing sidewalls 306c1, 306c2 and non-planar bonding surface 306d. Non-planar bonding surface 306d includes a planar portion 306d3 between angled portions 306d1, 306d2.

FIG. 3B illustrates contact portion 316c of terminal 316. Contact portion 316c includes upper surface 316c3, opposing sidewalls 316c1, 316c2 and non-planar bonding surface 316d. Non-planar bonding surface 316d includes a planar portion 316d3 between curved portions 316d1, 316d2.

FIG. 3C illustrates contact portion 326c of terminal 326. Contact portion 326c includes upper surface 326c3, and a continuous curved non-planar bonding surface 326d. Opposing sidewalls 326c1, 326c2 are part of the continuous curve including non-planar bonding surface 326d.

FIG. 3D illustrates contact portion 336c of terminal 336. Contact portion 336c includes non-planar bonding surface 336d. In FIG. 3D, non-planar bonding surface 336d has a spherical profile/shape. That is, non-planar bonding surface 336d is a portion of sphere. As used herein, the term “spherical” is intended to refer to any portion of a sphere, and as such is synonymous with “semi-spherical” or “partial spherical'”.

FIG. 3E illustrates contact portion 346c of terminal 346. Contact portion 346c includes non-planar bonding surface 346d. In FIG. 3E, non-planar bonding surface 336d has a conical profile/shape. That is, non-planar bonding surface 346d is cone-shaped. An example conical profile has a cone angle of approximately 2°.

Likewise, in FIG. 3F, non-planar bonding surface 356d of contact portion 356c (where contact portion 356c is part of terminal 356) has a conical profile/shape, except that the lower portion of the conical profile is planar.

FIG. 3G illustrates contact portion 366c of terminal 366. Contact portion 366c includes non-planar bonding surface 366d. In FIG. 3G, non-planar bonding surface 366d has a pyramidal profile/shape. That is, non-planar bonding surface 366d is pyramid-shaped. Likewise, in FIG. 3H, non-planar bonding surface 376d of contact portion 376c (where contact portion 376c is part of terminal 376) has a pyramidal profile/shape, except that the lower portion of the pyramidal profile is planar.

Thus, FIGS. 3A-3H (along with FIGS. 1B and 2B) illustrate various exemplary contact portions of respective terminals. These contact portions may be included as part of terminals having varying shapes (e.g., step down terminals such as in FIGS. 1A-1B, straight terminals, terminals having a single bend, etc.). These contact portions may be included as part of a terminal where the terminal is formed from a single piece of conductive material (e.g., copper material), and may further (or may not) be part of a busbar where the busbar is formed from a single piece of conductive material (e.g., copper material). While copper (or copper alloy) terminals and busbars are described herein, it is understood that the invention (and the associated terminals, busbars, and methods) are not limited to copper materials.

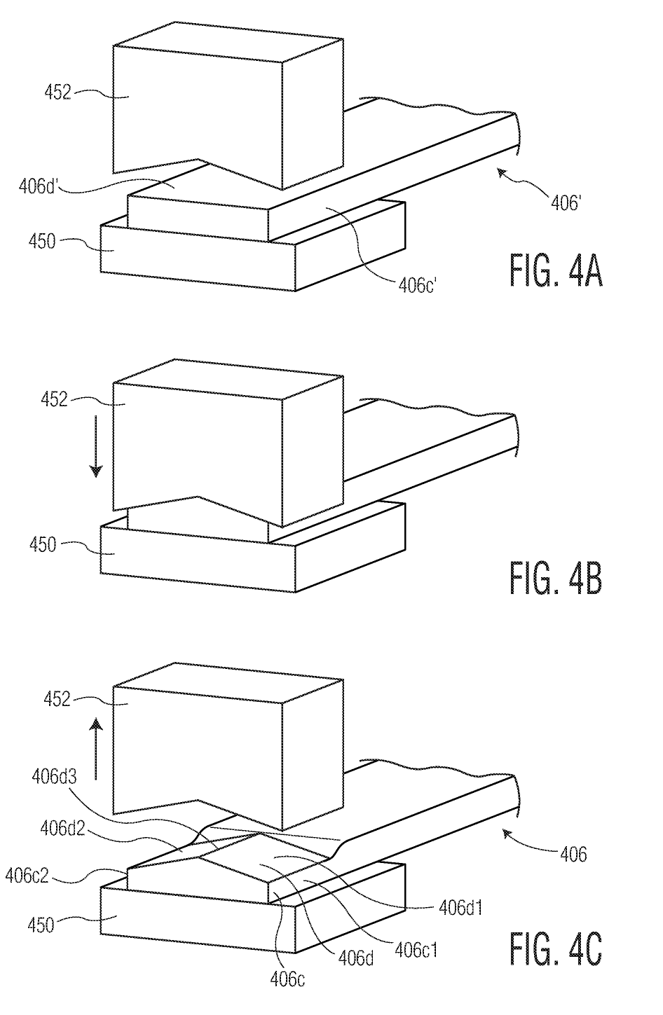

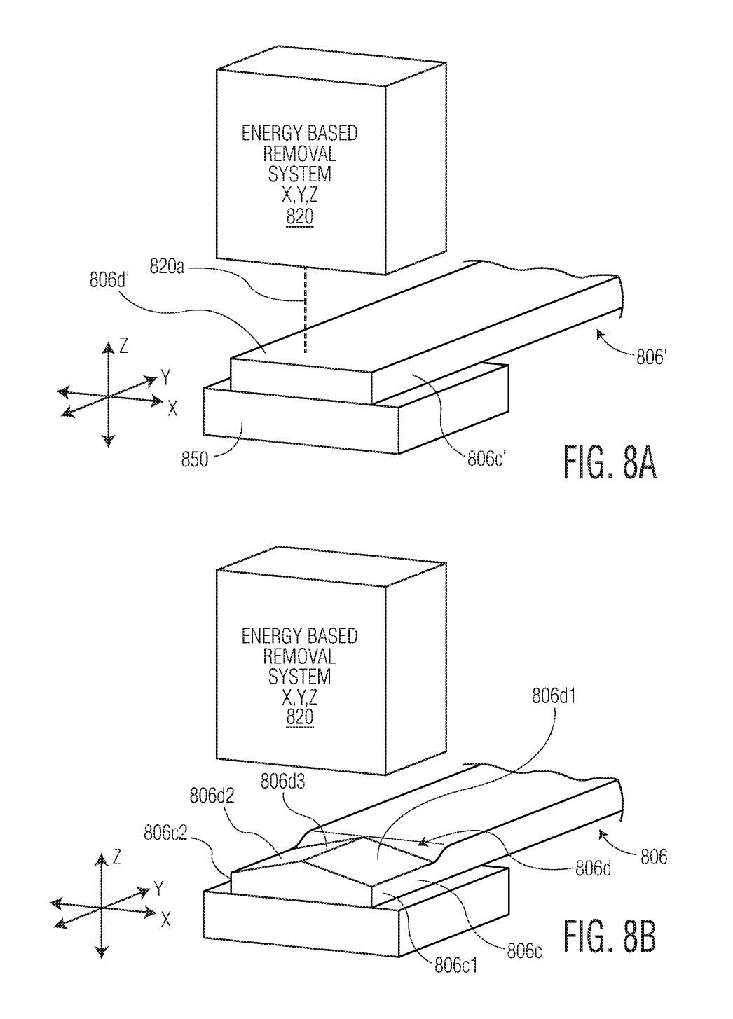

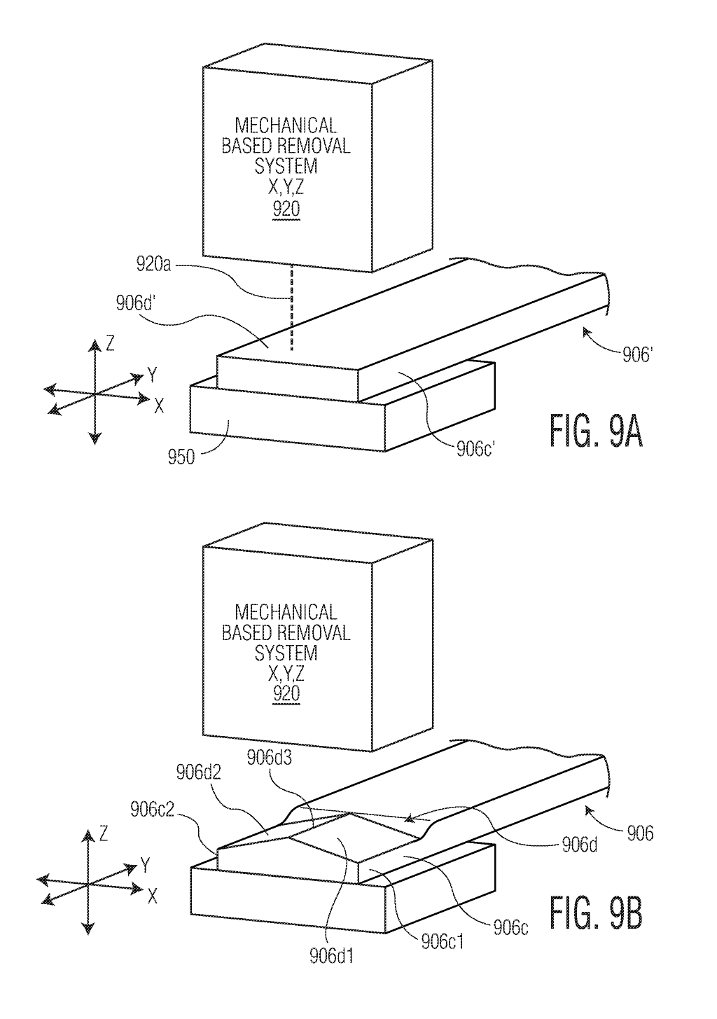

It will be appreciated that there are many methods of preparing the terminals (and/or related busbars) in accordance with the invention. For example, each of the terminals (and/or related busbars) illustrated in FIGS. 1B, 2B, and 3A-3H may be formed by pressing operations (e.g., stamping, coining, punching, etc. such as shown in FIGS. 4A-4C, FIG. 5, FIGS. 6A-6C, and FIG. 7), by methods of removing material (e.g., energy based removal as in FIGS. 8A-8B, mechanical based removal as in FIGS. 9A-9B, among other methods), or by other methods. Because of the variation in the methods of preparing such terminals (and/or related busbars) it is understood that details (e.g., the relative thickness of various portions of the terminals) of the various terminals illustrated herein may not be to scale.

FIGS. 4A-4C are block diagrams illustrating a method of preparing a terminal in accordance with an exemplary embodiment of the invention. FIG. 4A illustrates a conductive body portion (e.g., a copper body portion) of a terminal 406′ having a contact portion 406c′.Contact portion 406c′ includes planar bonding surface 406d′. Terminal 406′ is supported by anvil 450. Press 452 is positioned above planar bonding surface 406d′. Press 452 moves downwardly as shown in FIG. 4B, thereby pressing against planar bonding surface 406d′ of terminal 406′. As illustrated in FIG. 4C, after press 452 is raised, the downward pressing of FIG. 4B (along with the peaked recess defined by press 452) was sufficient to vary (i) planar bonding surface 406d′ of contact portion 406c′ of terminal 406′ to be (ii) non-planar surface 406d of contact portion 406c of terminal 406. Non-planar bonding surface 406d (shown in FIG. 4C) is substantially similar to non-planar bonding surface 106d of terminal 106 shown in FIG. 1B. Contact portion 406c (prepared through the pressing operation shown in FIG. 4B) is the portion of terminal 406 configured to be ultrasonically welded to another conductive location (e.g., to a conductive portion of a substrate). Because of non-planar bonding surface 406d, contact portion 406c of terminal 406 in FIG. 4C has a “pointed” or “peaked” profile. Contact portion 406c includes opposing sidewalls 406c1, 406c2. Non-planar bonding surface 406d is defined by opposing downwardly sloped sides 406d1, 406d2, joining at “peak” 406d3 (peak 406d3 may also be considered an “apex”).

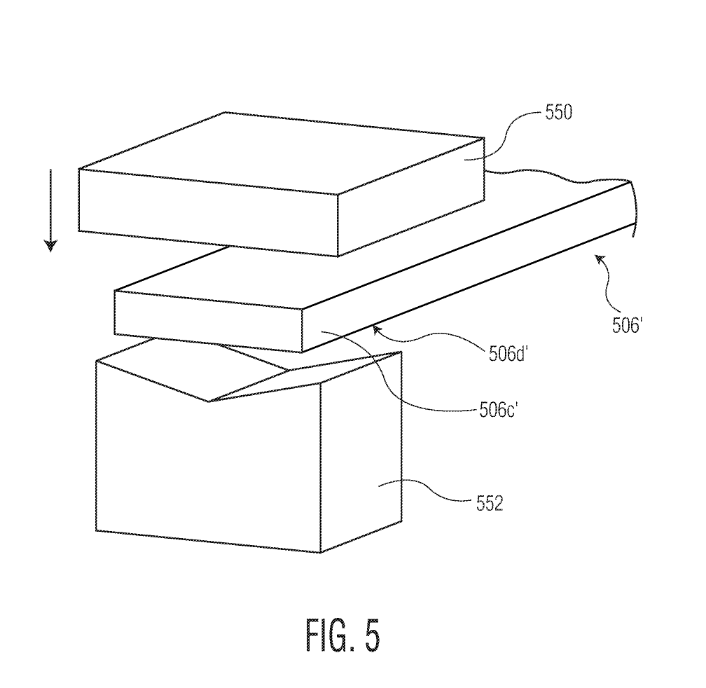

FIG. 5 is a block diagram illustrating elements of another system for preparing a terminal in accordance with an exemplary embodiment of the invention and is one alternative to the method illustrated in FIGS. 4A-4C. In FIGS. 4A-4C, the pressing member that moves to press the contact portion 406c′ is the “shaped” press 452. That is, anvil 450 is planar and does not move. However, it is understood that the pressing member (that moves) may be a planar member, and the stationary anvil may be the shaped member. Further, both the planar member and the shaped member may move in connection with the pressing operation to prepare the terminal.

Specifically, FIG. 5, is an example where the anvil 552 is “shaped” to define the desired shape of the non-planar bonding surface of the contact portion, resulting from the pressing of contact portion 506c′ with press 550. That is, press 550 includes a planar surface for pressing contact portion 506c′ of terminal 506′ against shaped anvil 552. Through such a pressing operation planar bonding surface 506d′ will become a non-planar bonding surface having a profile defined by the shape of the recess in anvil 552.

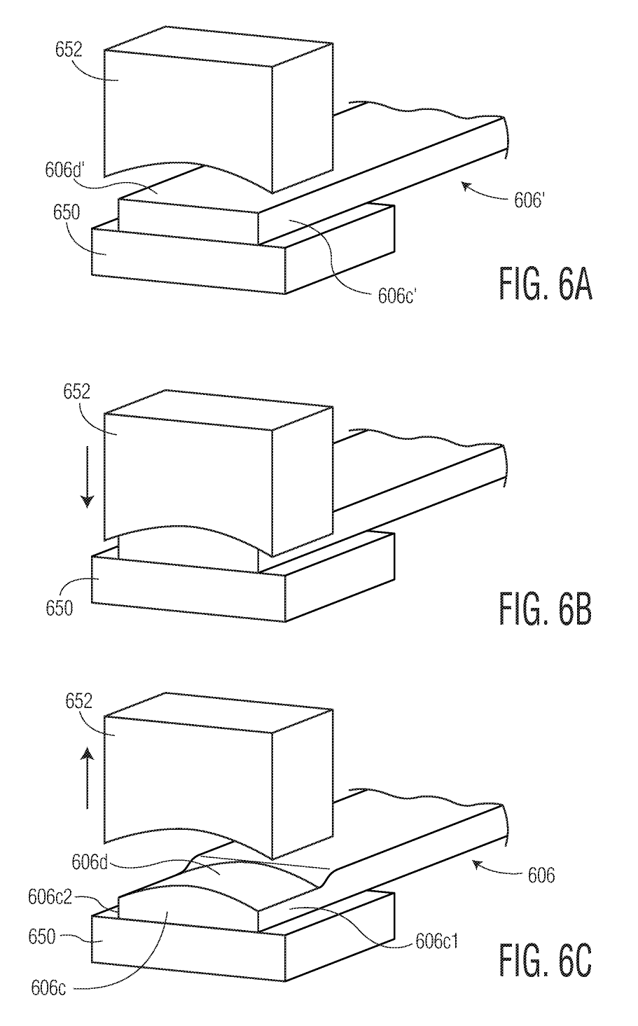

FIGS. 6A-6C are block diagrams illustrating another method of preparing a terminal in accordance with an exemplary embodiment of the invention. FIG. 6A illustrates a conductive body portion (e.g., a copper body portion) of a terminal 606′ having a contact portion 606c′. Contact portion 606c′ includes planar bonding surface 606d′. Terminal 606′ is supported by anvil 650. Press 652 is positioned above planar bonding surface 606d′. Press 652 moves downwardly as shown in FIG. 6B, thereby pressing against planar bonding surface 606d′ of terminal 606′. As illustrated in FIG. 6C, after press 652 is raised, the downward pressing of FIG. 6B (along with the curved recess defined by press 652) was sufficient to vary (i) planar bonding surface 606d′ of contact portion 606c′ of terminal 606′ to be (ii) non-planar surface 606d of contact portion 606c of terminal 606. Non-planar bonding surface 606d (shown in FIG. 6C) is substantially similar to non-planar bonding surface 206d of terminal 206 shown in FIG. 2B. Contact portion 606c (prepared through the pressing operation shown in FIG. 6B) is the portion of terminal 606 configured to be ultrasonically welded to another conductive location (e.g., to a conductive portion of a substrate). Because of non-planar bonding surface 606d, contact portion 606c of terminal 606 in FIG. 6C has a “curved” profile. Contact portion 606c includes opposing sidewalls 606c1, 606c2. Non-planar bonding surface 606d is defined by an arc-shaped curve.

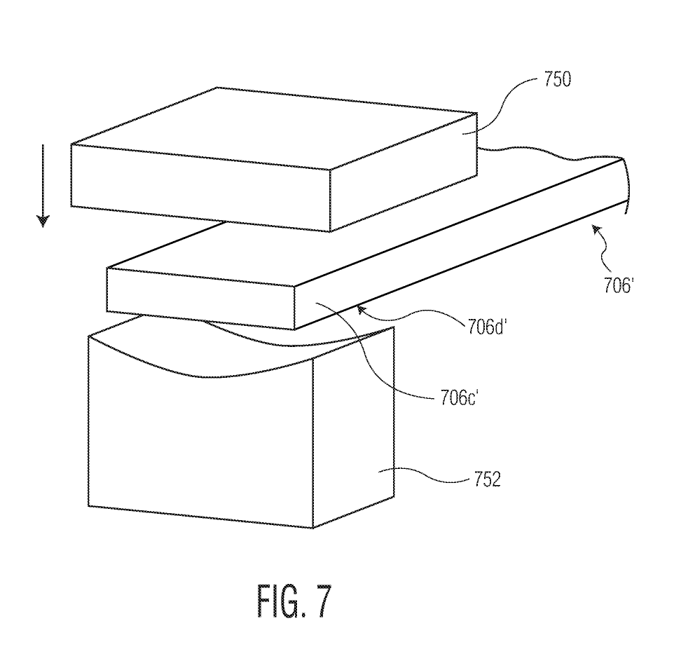

Similar to the difference between FIG. 5 and FIGS. 4A-4C, FIG. 7 provides an alternative to the method (and related structure) of FIGS. 6A-6C. Specifically, FIG. 7 is an example where the anvil 752 is “shaped” to define the desired shape (e.g., a curved surface) of the non-planar bonding surface of the contact portion, resulting from the pressing of contact portion 706c′ with press 750. That is, press 750 (which moves in relation to anvil 752 as shown by the downward arrow in FIG. 7) includes a planar surface for pressing contact portion 706c′ of terminal 706′ against shaped anvil 752. Through such a pressing operation planar bonding surface 706d′ will become a non-planar bonding surface having a profile (e.g., a curved profile) defined by the shape of the recess in anvil 752.

It is noted that there are varying processes for preparing a terminal (and/or a related busbar) to be ultrasonically welded to a substrate. For example, FIGS. 4A-4C, FIG. 5, FIGS. 6A-6C, and FIG. 7 all relate to some form of pressing operation (e.g., coining, stamping, punching or some other pressing operation) to vary the profile of the contact portion of a terminal. However, other methods of preparing a terminal (and/or a related busbar) are contemplated. For example, FIGS. 8A-8B and FIGS. 9A-9B illustrate two examples where material is removed from a terminal having contact portion with a planar bonding surface, such that the bonding surface becomes non-planar.

Referring specifically to FIGS. 8A-8B, an energy based removal system 820 is provided to remove material (e.g., copper material) from planar bonding surface 806d′ of contact portion 806c′ of terminal 806′. FIG. 8A illustrates terminal 806′ supported by anvil 850 with energy based removal system 820 positioned above planar bonding surface 806d′. Energy based removal system 820 may move (and/or act to emit energy in any desired direction, or along any desired axes (e.g., FIGS. 8A-8B indicate potential motion (and/or action of energy emission) of energy based removal system 820 along x, y and/or z axes). Energy based removal system 820 may include any type of energy system useful for removing material from the applicable terminal. Examples of such energy based removal systems include EDM (electro discharge machining) based removal systems, laser based removal systems, among others. Energy based removal system 820 acts upon contact portion 806c′ of terminal 806′ as shown by dashed line 820a (indicating application of energy from energy based removal system 820), thereby removing material from planar bonding surface 806d′ to form shaped non-planar bonding surface 806d as shown in FIG. 8B (where contact portion 806c′ is now referred to as 806c, and terminal 806′ is now referred to as terminal 806). Non-planar bonding surface 806d is configured to be ultrasonically welded to another location. Because of non-planar bonding surface 806d, contact portion 806c of terminal 806 in FIG. 8B has a “pointed” or “peaked” profile. Contact portion 806c includes opposing sidewalls 806c1, 806c2. Non-planar bonding surface 806d is defined by opposing downwardly sloped sides 806d1, 806d2, joining at “peak” 806d3 (peak 806d3 may also be considered an “apex”).

Referring specifically to FIGS. 9A-9B, a mechanical based removal system 920 is provided to remove material (e.g., copper material) from planar bonding surface 906d′ of contact portion 906c′ of terminal 906′. FIG. 9A illustrates terminal 906′ supported by anvil 950 with mechanical based removal system 920 positioned above planar bonding surface 906d′. Mechanical based removal system 920 may move in any desired direction, or along any desired axes (e.g., FIGS. 9A-9B indicate potential motion of mechanical based removal system 920 along x, y and/or z axes). Mechanical based removal system 920 may include any type of mechanical system useful for removing material from the applicable terminal. Examples of such mechanical based removal systems include milling systems, grinding systems, machining systems, among others. Mechanical based removal system 920 acts upon contact portion 906c′ of terminal 906′ as shown by dashed line 920a (indicating application of the relevant mechanical systems element such as a blade, grinding wheel, etc. from mechanical based removal system 920), thereby removing material from planar bonding surface 906d′ to form shaped non-planar bonding surface 906d as shown in FIG. 9B (where contact portion 906c′ is now referred to as 906c, and terminal 906′ is now referred to as terminal 906). Non-planar bonding surface 906d is configured to be ultrasonically welded to another location. Because of non-planar bonding surface 906d, contact portion 906c of terminal 906 in FIG. 9B has a “pointed” or “peaked” profile. Contact portion 906c includes opposing sidewalls 906c1, 906c2. Non-planar bonding surface 906d is defined by opposing downwardly sloped sides 906d1, 906d2, joining at “peak” 906d3 (peak 906d3 may also be considered an “apex”).

While the methods of FIGS. 4A-4C, FIG. 5, FIGS. 6A-6C, FIG. 7, FIGS. 8A-8B, and FIGS. 9A-9B relate to methods of preparing terminals (and/or related busbars) with contact portions having specific profiles (e.g., peaked or curve profiles), such methods (and systems) are relevant for preparation of any type of terminals (and/or related busbars) within the scope of the invention.

Further, instead of preparing an existing terminal to have the desired non-planar bonding surface - aspects of the invention relate to formation of the initial terminal to have such a non-planar bonding surface. That is, all details described herein related to inventive terminals may be applied to the terminals during their initial creation. Subsequent processing/preparation, to vary the profile of an existing termination (such as in FIGS. 4A-4C, FIG. 5, FIGS. 6A-6C, FIG. 7, FIGS. 8A-8B, and FIGS. 9A-9B) is not needed in such cases.

It will be appreciated that the term “power module” (sometimes referred to as a power electronic module), as used herein, relates to a module for containing one or more power components (e.g., power semiconductor devices). Example power components include MOSFETs, IGBTs, BJTs, thyristors, GTPs, and JFETs. Such a module also typically includes a power electronic substrate for carrying the power components. As compared to discrete power semiconductors, power modules tend to provide a higher power density. As will be appreciated by those skilled in the art, the power modules illustrated in the drawings herein (e.g., power modules 1000, 1000′, 1100, and 1100′) are simplified for ease of illustration,

FIG. 10A illustrates power module 1000 (where terminals 106 of busbar 100 have not yet been ultrasonically welded to bonding locations in power module 1000). Busbar 100 (which is the same as busbar 100 from FIG. 1, but could be any busbar within the scope of the invention) is aligned over intervening structure 1002 (i.e., any structure which may be included in power module 1000), which in turn is supported by substrate 1004 (e.g., a copper substrate) directly or indirectly. Busbar 100 is configured to provide electrical interconnection within power module 1000. Busbar 100 includes conductive distribution body portion 102 and plurality of conductive terminals 106 extending from conductive distribution body portion 102. Each terminal 106 includes a contact portion 106c having a non-planar (peaked) bonding surface 106d configured to be ultrasonically welded to a bonding area 1004a of substrate 1004. FIG. 10B illustrates sonotrode 1006b carried by ultrasonic converter 1006a, both included in weld head assembly 1006 of an ultrasonic welding machine. In FIG. 10B, sonotrode 1006b (e.g., using linear ultrasonic scrub, torsional/rotational ultrasonic scrub, etc.) ultrasonically welds contact portion 106c of the left most terminal 106 to bonding area 1004a of substrate 1004. This operation is complete in FIG. 10C, where terminal 106 is now referred to as welded terminal 106′. Welded terminal 106′ includes welded portion 106′a (illustrated as a round welded portion, which may be formed using torsional/rotational ultrasonic scrub) and welded interface 106′b. It is noteworthy that welded interface 106′b is now substantially planar (as opposed to the peaked profile shown in FIGS. 10A-10B) due to the ultrasonic welding operation. At FIG. 10D, all terminals 106 have been ultrasonically welded, and are now referred to as welded terminals 106′. With these welded terminals 106′, power module 1000 is now referred to as power module 1000′.

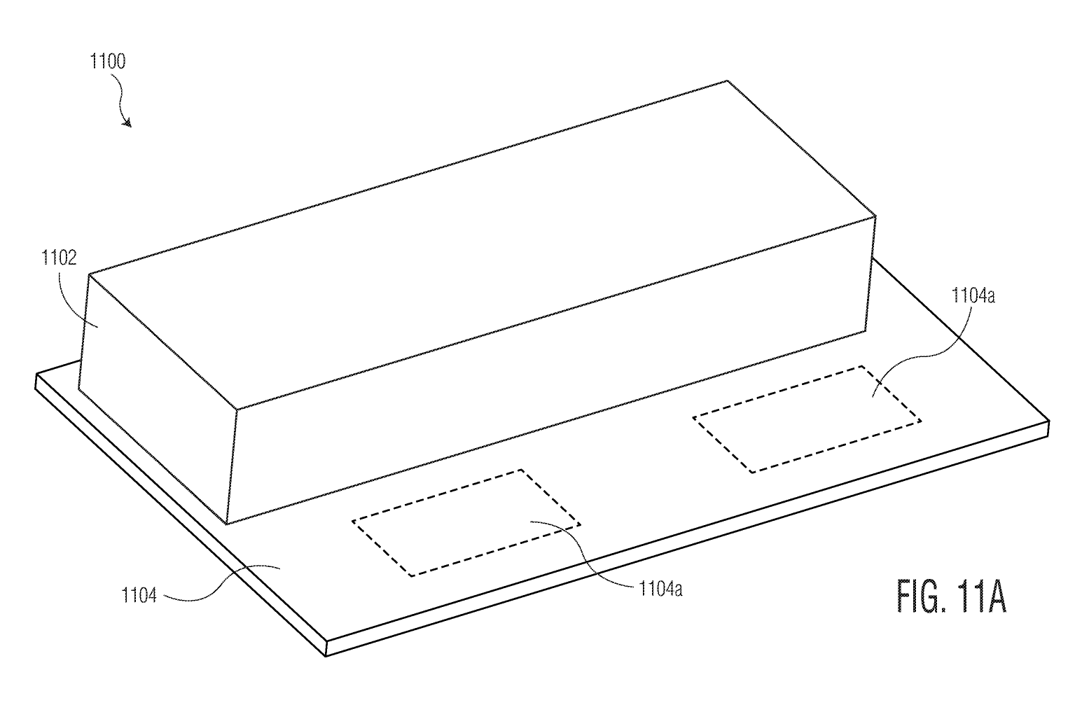

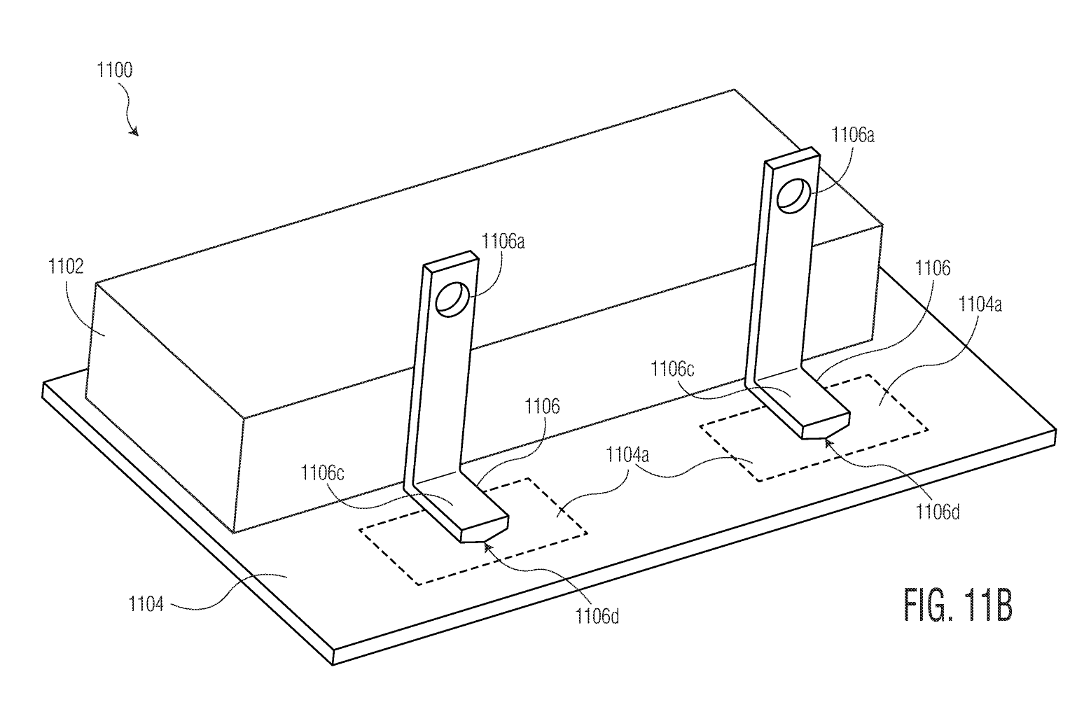

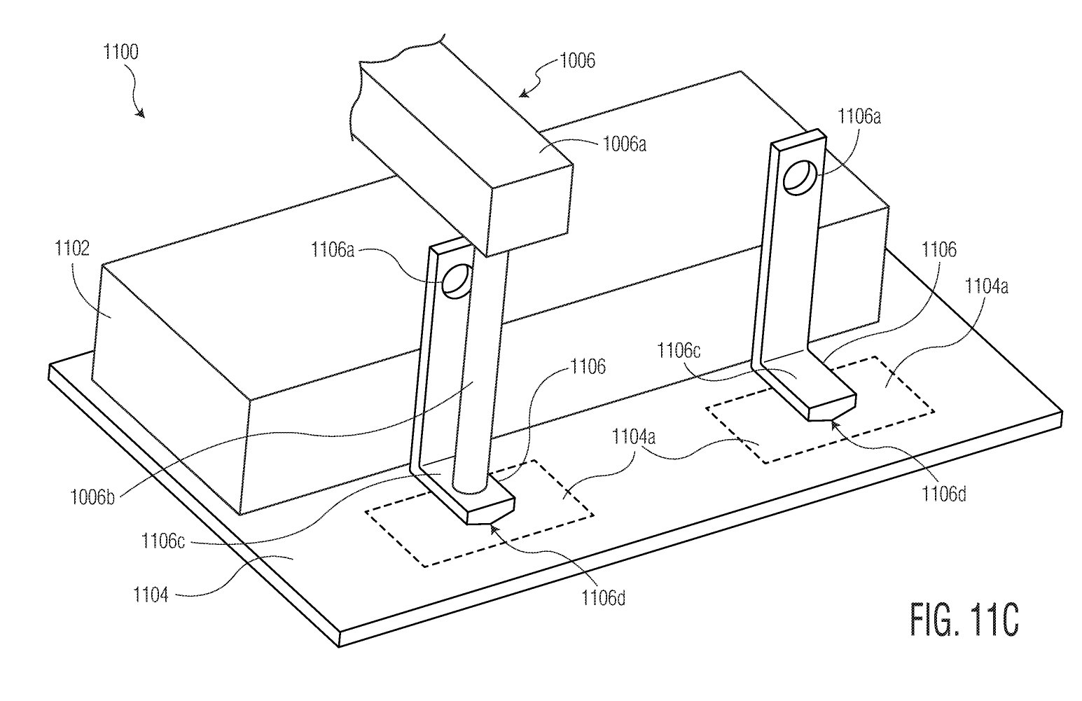

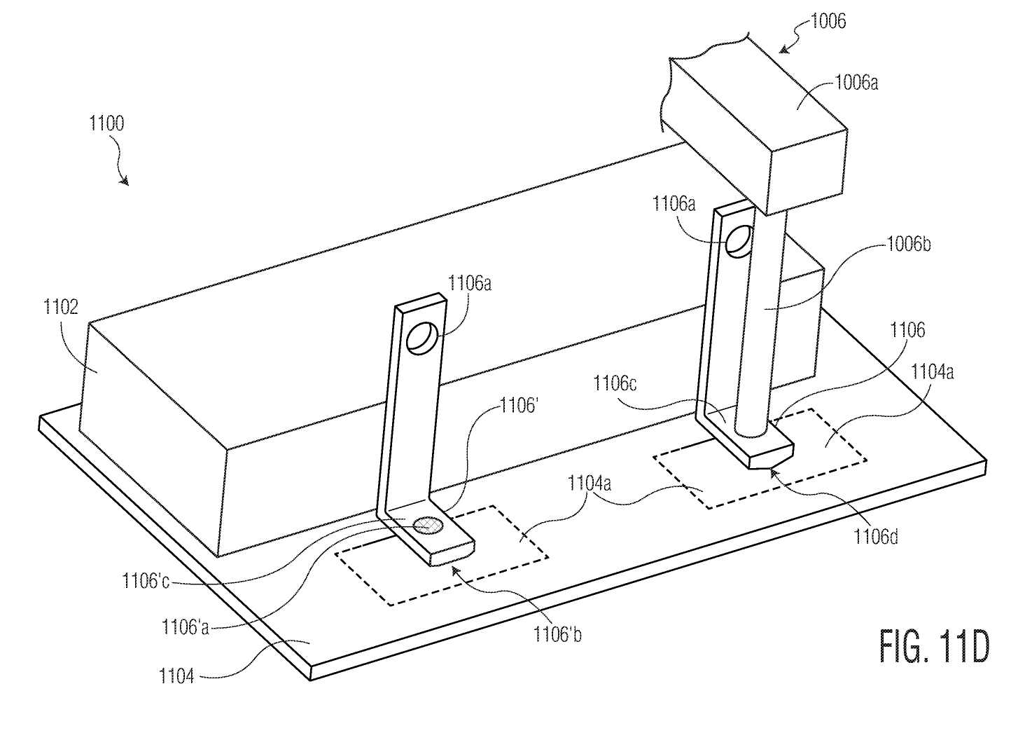

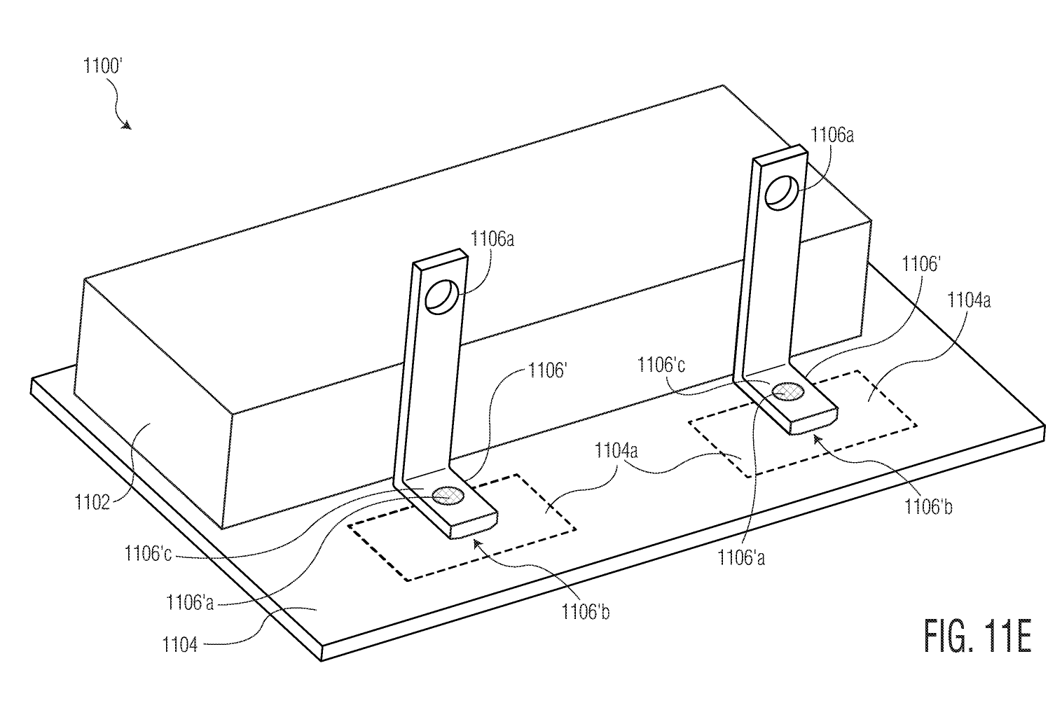

Of course, FIGS. 10A-10D illustrate just one example of a method of assembling a power module. FIGS. 11A-11E illustrate one more example. As opposed to terminals 106 included as part of a busbar 100 as shown in FIG. 10A, FIGS. 11A-11E relate to ultrasonic welding of individual terminals 1106 not included as part of a busbar.

FIG. 11A illustrates power module 1100 including intervening structure 1102 (i.e., any structure which may be included in power module 1100) and bonding locations 1104a included in substrate 1104 (e.g., a copper substrate). In FIG. 11B, conductive terminals 1106 have been aligned with corresponding bonding locations 1104a of substrate 1104. While two conductive terminals 1106 are shown aligned in FIG. 11B, it is understood that each conductive terminal 1106 may be aligned one at a time prior to ultrasonic welding. Of course, additional conductive terminals 1106 may be included. Conductive terminals 1106 are configured to provide electrical interconnection in power module 1100. Each conductive terminal 1106 includes a conductive body portion having a connection point 1106a (for connecting to another location, such as an electrical connection from outside of power module 1100) and a contact portion 1106c configured to be ultrasonically welded to the bonding location. Contact portion 1106c includes a non-planar bonding surface 1106d.

FIG. 11C illustrates sonotrode 1006b carried by ultrasonic converter 1006a, both included in weld head assembly 1006 of an ultrasonic welding machine. In FIG. 11C, sonotrode 1006b (e.g., using linear ultrasonic scrub, torsional/rotational ultrasonic scrub, etc.) ultrasonically welds contact portion 1106c of the left most terminal 1106 to bonding location 1104a of substrate 1104. This operation is complete in FIG. 11D, where terminal 1106 is now referred to as welded terminal 1106′. Welded terminal 1106′ includes welded contact portion 1106′c including welded portion 1106′a (illustrated as a round welded portion, which may be formed using torsional/rotational ultrasonic scrub) and welded interface 1106′b. It is noteworthy that welded interface 1106′b is now substantially planar (as opposed to the peaked profile shown in FIGS. 11B-11C) due to the ultrasonic welding operation. At FIG. 11D, the other terminal 1106 is being ultrasonically welded to a bonding location 1104a of substrate 1104. At FIG. 11E, both terminals 1106 have been ultrasonically welded, and are now referred to as welded terminals 1106′. With these welded terminals 1106′, power module 1100 is now referred to as power module 1100′.

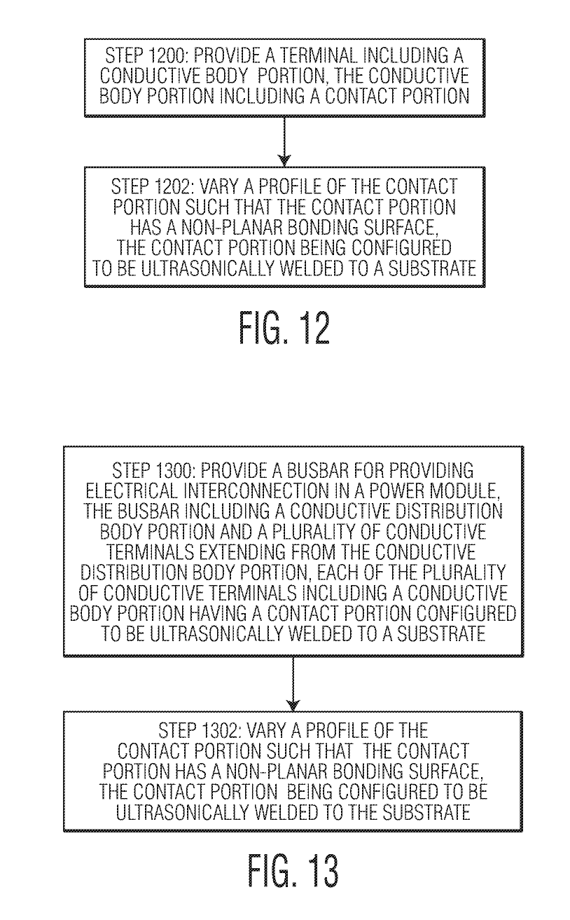

FIGS. 12-15 are flow diagrams illustrating methods of processing bonding tools in accordance with various exemplary embodiments of the invention. As is understood by those skilled in the art: certain steps included in the flow diagrams may be omitted; certain additional steps may be added; and the order of the steps may be altered from the order illustrated.

Referring specifically to FIG. 12, a method of preparing a terminal configured to be ultrasonically welded to a substrate is provided. At Step 1200, a terminal (e.g., terminal 406′, terminal 506′, terminal 606′, terminal 706′, terminal 806′, terminal 906′, among other terminals within the scope of the invention) including a conductive body portion is provided. The conductive body portion includes a contact portion. At Step 1202, a profile of the contact portion (e.g., using the methods shown in FIGS. 4A-4C, FIG. 5, FIGS. 6A-6C, FIG. 7, FIGS. 8A-8B, FIGS. 9A-9B, among other methods within the scope of the invention) is varied such that the contact portion has a non-planar bonding surface, the contact portion being configured to be ultrasonically welded to a substrate.

Referring specifically to FIG. 13, a method of preparing a busbar configured to be ultrasonically welded to a substrate is provided. At Step 1300, a busbar (e.g., a busbar including terminals 406′, terminal 506′, terminal 606′, terminal 706′, terminal 806′, terminal 906′, or any busbar within the scope of the invention) for providing electrical interconnection in a power module is provided. The busbar includes a conductive distribution body portion and a plurality of conductive terminals extending from the conductive distribution body portion, with each of the plurality of conductive terminals including a conductive body portion having a contact portion configured to be ultrasonically welded to a substrate. At Step 1302, a profile of the contact portion is varied (e.g., using the methods shown in FIGS. 4A-4C, FIG. 5, FIGS. 6A-6C, FIG. 7, FIGS. 8A-8B, FIGS. 9A-9B, among other methods within the scope of the invention) such that the contact portion has a non-planar bonding surface, the contact portion being configured to be ultrasonically welded to the substrate.

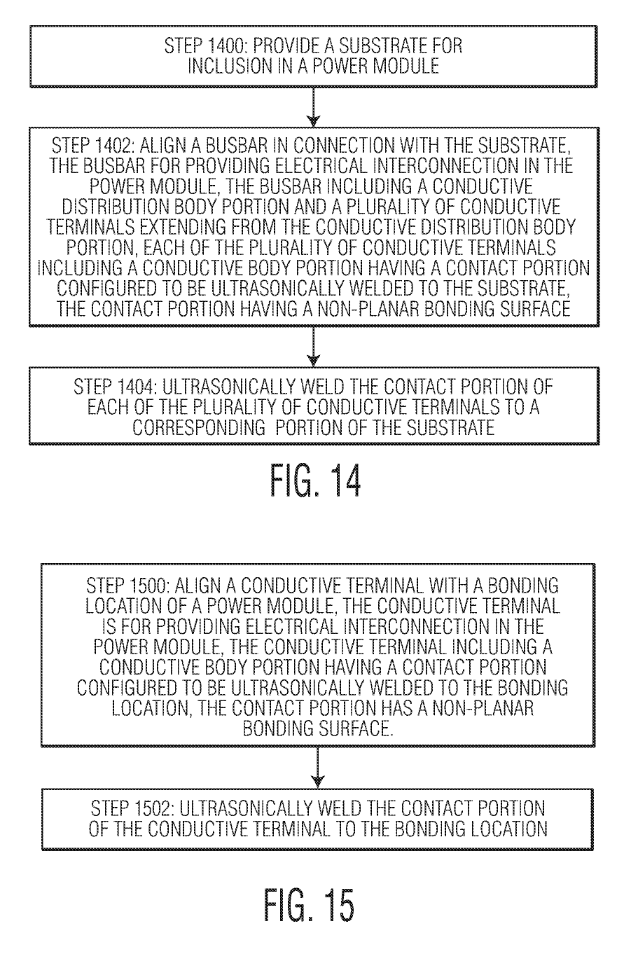

Referring specifically to FIG. 14, a method of assembling a power module is provided. At Step 1400, a substrate (e.g., substrate 1004 in FIGS. 10A-10D) for inclusion in a power module is provided. At Step 1402, a busbar (e.g., busbar 100 in FIGS. 10A-10D) is aligned in connection with the substrate. The busbar provides electrical interconnection in the power module, and includes a conductive distribution body portion and a plurality of conductive terminals extending from the conductive distribution body portion. Each of the plurality of conductive terminals includes a conductive body portion having a contact portion configured to be ultrasonically welded to the substrate, with the contact portion having a non-planar bonding surface. At Step 1404, the contact portion of each of the plurality of conductive terminals is ultrasonically welded to a corresponding portion of the substrate (e.g., see welded terminals 106′ in FIGS. 10C-10D).

Referring specifically to FIG. 15, at Step 1500, another method of assembling a power module is provided. At Step 1500, a conductive terminal (e.g., conductive terminal 1106 in FIGS. 11B-11D) is aligned with a bonding location of the power module. The conductive terminal is for providing electrical interconnection in the power module. The conductive terminal includes a conductive body portion having a contact portion configured to be ultrasonically welded to the bonding location. The contact portion has a non-planar bonding surface. At Step 1502, the contact portion of the conductive terminal is ultrasonically welded to the bonding location (e.g., see welded terminals 1106′ in FIGS. 11D-11E).

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A terminal configured to be ultrasonically welded to a substrate, the terminal comprising:
a conductive body portion including a contact portion configured to be ultrasonically welded to a substrate,
the contact portion having a non-planar bonding surface.

2. The terminal of claim 1 wherein the non-planar bonding surface defines at least one of a peaked profile, a curved profile, a conical profile, a pyramidal profile, and a spherical profile.

3. The terminal of claim 1 wherein the terminal is formed from a copper material.

4. A busbar for providing electrical interconnection in a power module, the busbar comprising:
a conductive distribution body portion; and
a plurality of conductive terminals extending from the conductive distribution body portion, each of the plurality of conductive terminals including a conductive body portion having a contact portion configured to be ultrasonically welded to a substrate, the contact portion having a non-planar bonding surface.

5. The busbar of claim 4 wherein the conductive distribution body portion and the plurality of conductive terminals are formed from a unitary piece of material.

6. The busbar of claim 4 wherein the non-planar bonding surface defines at least one of a peaked profile, a curved profile, a conical profile, a pyramidal profile, and a spherical profile.

7. The busbar of claim 4 wherein the busbar is formed from a copper material.

8. A method of preparing a terminal configured to be ultrasonically welded to a substrate, the method comprising the steps of:
(a) providing a terminal including a conductive body portion, the conductive body portion including a contact portion; and
(b) varying a profile of the contact portion such that the contact portion has a non-planar bonding surface, the contact portion being configured to be ultrasonically welded to a substrate.

9. The method of claim 8 wherein step (b) includes pressing the contact portion with a press to vary the profile of the contact portion.

10. The method of claim 9 wherein the pressing of step (b) includes at least one of coining, stamping, and punching the contact portion with the press to vary the profile of the contact portion.

11. The method of claim 8 wherein step (b) includes removing material from the contact portion to vary the profile of the contact portion.

12. The method of claim 11 wherein step (b) includes at least one of milling, machining and grinding the contact portion to vary the profile of the contact portion.

13. The method of claim 8 wherein the terminal is formed from a copper material.

14. The method of claim 8 wherein step (b) includes varying the profile of the contact portion such that the non-planar bonding surface defines at least one of a peaked profile, a curved profile, a conical profile, a pyramidal profile, and a spherical profile.

15. A method of preparing a busbar configured to be ultrasonically welded to a substrate, the method comprising the steps of:
(a) providing a busbar for providing electrical interconnection in a power module, the busbar including a conductive distribution body portion and a plurality of conductive terminals extending from the conductive distribution body portion, each of the plurality of conductive terminals including a conductive body portion having a contact portion configured to be ultrasonically welded to a substrate; and
(b) varying a profile of the contact portion such that the contact portion has a non-planar bonding surface, the contact portion being configured to be ultrasonically welded to the substrate.

16. The method of claim 15 wherein step (b) includes pressing the contact portion with a press to vary the profile of the contact portion.

17. The method of claim 16 wherein the pressing of step (b) includes at least one of coining, stamping, and punching the contact portion with the press to vary the profile of the contact portion.

18. The method of claim 15 wherein step (b) includes removing material from the contact portion to vary the profile of the contact portion.

19. The method of claim 18 wherein step (b) includes at least one of milling, machining and grinding the contact portion to vary the profile of the contact portion.

20. The method of claim 15 wherein the terminal is formed from a copper material.

21. The method of claim 15 wherein step (b) includes varying the profile such that the non-planar bonding surface defines at least one of a peaked profile, a curved profile, a conical profile, a pyramidal profile, and a spherical profile.

22. A method of assembling a power module, the method comprising the steps of:
(a) providing a substrate for inclusion in a power module;
(b) aligning a busbar in connection with the substrate, the busbar for providing electrical interconnection in the power module, the busbar including a conductive distribution body portion and a plurality of conductive terminals extending from the conductive distribution body portion, each of the plurality of conductive terminals including a conductive body portion having a contact portion configured to be ultrasonically welded to the substrate, the contact portion having a non-planar bonding surface; and
(c) ultrasonically welding the contact portion of each of the plurality of conductive terminals to a corresponding portion of the substrate.

23. A method of assembling a power module, the method comprising the steps of:
(a) aligning a conductive terminal with a bonding location of the power module, the conductive terminal for providing electrical interconnection in the power module, the conductive terminal including a conductive body portion having a contact portion configured to be ultrasonically welded to the bonding location, the contact portion having a non-planar bonding surface; and
(b) ultrasonically welding the contact portion of the conductive terminal to the bonding location.
